(19) United States
(12) Patent Application Publication
(10) Pub. No.: US 2026/0110723 A1
(43) Pub. Date: Apr. 23, 2026

(54) A PROTECTION METHOD FOR AN ELECTRICAL DISTRIBUTION SYSTEM

(71) Applicant: Hitachi Energy Ltd, Zürich (CH)

(72) Inventors: ChunMing Yuan, Beijing (CN); Daniel Siemaszko, Ste-Croix (CH); Javier Iglesias, Madrid (ES)

(21) Appl. No.: 19/168,370

(22) PCT Filed: Apr. 19, 2023
(86) PCT No.: PCT/EP2023/060142

§ 371 Date: Sep. 24, 2025

(30) Foreign Application Priority Data
Mar. 30, 2023 (EP) 23382303.8

(51) Int. Cl. G01R 31/08; H02H 7/26; H02H 9/02; H02J 13/12; H02J 13/34

(52) U.S. Cl. CPC G01R 31/086; H02H 7/266; H02H 7/268; H02H 9/02; H02J 13/12; H02J 13/34

(57) ABSTRACT

A method and a controller for protecting an electrical distribution system are disclosed. The electrical distribution system comprises an electrical grid being electrically coupled to an electrical branch. The electrical branch comprises a plurality of switches for connecting or disconnecting the electrical branch at respective positions on the electrical branch, wherein a load is electrically coupled to a node on the electrical branch. The method comprises: detecting a fault occurrence on the electrical branch based on a monitored voltage and/or current of the electrical branch; limiting, based on the detecting a fault occurrence, a power flow from the node to the load; adjusting, based on the detecting a fault occurrence, a voltage and/or current on the electrical branch; determining a fault location based on the adjusted voltage and/or current on the electrical branch; and disconnecting a portion of the electrical distribution system based on the determined fault location.

### CROSS REFERENCE TO RELATED APPLICATIONS

This application is a 35 U.S.C. § 371 national stage application of PCT International Application No. PCT/EP2023/060142 filed on Apr. 19, 2023, which in turn claims priority to European Patent Application No. 23382303.8, filed on Mar. 30, 2023, the disclosures and content of which are incorporated by reference herein in their entireties.

### TECHNICAL FIELD

The present disclosure relates to a method, controller, and an electrical distribution system for protecting the electrical distribution system.

### BACKGROUND

In an electrical power distribution system, delivering a power from power sources to loads, a fault causes numerous issues. A conventional solution of the fault clearance is to install DC circuit breakers in order to block the path through which the power flows. Such a solution however not only increases the power losses during an operation but is also cost ineffective.

FIG. 1 illustrates a conventional medium voltage DC (MVDC) system for a data center application. In FIG. 1, the power is delivered from the high-level power source, e.g., an AC network, to the IT loads through the power converters and busses that are electrically coupling the power source to the loads. In particular, the grid AC/DC rectifier electrically couples the power source to the MVDC bus and converts the power from the power source to be further distributed through the MVDC bus to the IT rooms. Each IT room comprises galvanic isolators for stepping down the MVDC voltage to a low voltage DC (LVDC) level which is consumed by the IT loads and the battery connected to the LVDC bus. Besides the illustrated data center application, another typical application includes a MVDC power distribution system for DC loads of electrical vehicle charging stations (EVCS), in particular in conjunction with the battery energy storage being electrically coupled thereto. In such MVDC system, a short-circuit fault causes numerous issues and the conventional fault clearance solution increases power losses and is cost ineffective.

Thus, there is a need to improve a method, controller, and an electrical distribution system for protecting the electrical distribution system.

### SUMMARY

The present disclosure relates to a method for protecting an electrical distribution system comprising an electrical grid being electrically coupled to an electrical branch, the electrical branch comprising a plurality of switches for connecting or disconnecting the electrical branch at respective positions on the electrical branch, wherein a load is electrically coupled to a node on the electrical branch, the method comprising: detecting a fault occurrence on the electrical branch based on a monitored voltage and/or current of the electrical branch; limiting, based on the detecting a fault occurrence, a power flow from the node to the load; adjusting, based on the detecting a fault occurrence, a voltage and/or current on the electrical branch; determining a fault location based on the adjusted voltage and/or current on the electrical branch; and disconnecting a portion of the electrical distribution system based on the determined fault location.

In an embodiment, the limiting is or comprises controlling a galvanic isolator electrically coupling load to the node.

In an embodiment, the adjusting is or comprises injecting a predetermined current into the electrical branch, in particular by controlling a power converter electrically coupling the electrical grid to the electrical branch, and a fault location is determined based on the adjusted current.

In an embodiment, the method further comprises limiting, prior to the disconnecting, a power flow from the electrical grid to the electrical branch, in particular by controlling a power converter electrically coupling the electrical grid to the electrical branch.

In an embodiment, the disconnecting is or comprises disconnecting at least two switches of the plurality of switches, when having determined that a fault location resides on the branch between the at least two switches.

In an embodiment, the at least two switches of the plurality of switches are adjacent to each other, in particular having the node located between the at least two switches.

In an embodiment, the method further comprises re-operating the power distribution system by: de-limiting, after the disconnecting, the limited power flow from the node to the load; and controlling, after the disconnecting, a power flow from the electrical grid to the load.

In an embodiment, two ends of the electrical branch are electrically coupled to a power converter, electrically coupling the electrical grid to the electrical branch, forming a loop.

In an embodiment, one end of two ends of the electrical branch is electrically coupled to a first power converter being further electrically coupled to the electrical grid and the other end of the two ends of the electrical branch is electrically coupled to a second power converter being further electrically coupled to the electrical grid.

In an embodiment, at least one of the plurality of switches disconnects the electrical branch.

In an embodiment, the adjusting further comprises enabling a power flow from the electrical grid to the electrical branch, in particular by controlling the second power converter.

In an embodiment, the adjusting is or comprises injecting a predetermined current into the electrical branch, in particular by controlling the first power converter and the second power converter.

In an embodiment, the determining a fault location is based on the adjusting the current on the electrical branch.

In an embodiment, the method further comprises re-operating the power distribution system by: de-limiting, after the disconnecting, the limited power flow from the node to the load; and enabling, after the disconnecting, a power flow from the electrical grid to the load, in particular by controlling the first power converter and the second power converter.

The present disclosure further relates to a controller for protecting an electrical distribution system comprising an electrical grid being electrically coupled to an electrical branch, the electrical branch comprising a plurality of switches for connecting or disconnecting the electrical branch at respective positions on the electrical branch, wherein a load is electrically coupled to a node on the electrical branch, the controller being configured to: detect a fault occurrence on the electrical branch based on a monitored voltage and/or current of the electrical branch; limit, based on the detecting a fault occurrence, a power flow from the node to the load; adjust, based on the detecting a fault occurrence, a voltage and/or current on the electrical branch; determine a fault location based on the adjusted voltage and/or current on the electrical branch; and disconnect a portion of the electrical distribution system based on the determined fault location.

In an embodiment, the controller is further configured to perform the method according to any one of the embodiments disclosed herein.

The present disclosure further relates to an electrical distribution system comprising an electrical grid being electrically coupled to an electrical branch, the electrical branch comprising a plurality of switches for connecting or disconnecting the electrical branch at respective positions on the electrical branch, wherein a load is electrically coupled to a node on the electrical branch, the electrical distribution system further comprising the controller according to any one of the embodiments disclosed herein.

The method according to any one of the embodiments disclosed herein may advantageously monitor and/or estimate quantities for an industrial asset, such as operational performance, operational state, or information on external conditions or adjacent systems. One particular quantity to monitor and/or estimate is the state of health of an industrial asset, which allows the degradation of the asset to be understood, its remaining useful life (RUL) to be predicted, and decisions for operation, maintenance, and repair to be derived. The information thus obtained can be used for informing human operators, managers, or stakeholders, to support their operational or other decisions, or to partly or fully automate the operation of the asset.

Various exemplary embodiments of the present disclosure are directed to providing features that will become readily apparent by reference to the following description when taken in conjunction with the accompanying drawings. In accordance with various embodiments, exemplary systems, methods, and devices are disclosed herein. It is understood, however, that these embodiments are presented by way of example and not limitation, and it will be apparent to those of ordinary skill in the art who read the present disclosure that various modifications to the disclosed embodiments can be made while remaining within the scope of the present disclosure.

Thus, the present disclosure is not limited to the exemplary embodiments and applications described and illustrated herein. Additionally, the specific order and/or hierarchy of steps in the methods disclosed herein are merely exemplary approaches. Based upon design preferences, the specific order or hierarchy of steps of the disclosed methods or processes can be rearranged while remaining within the scope of the present disclosure. Thus, those of ordinary skill in the art will understand that the methods and techniques disclosed herein present various steps or acts in a sample order, and the present disclosure is not limited to the specific order or hierarchy presented unless expressly stated otherwise.

In the following, exemplary embodiments of the present disclosure will be described. It is noted that some aspects of any one of the described embodiments may also be found in some other embodiments unless otherwise stated or obvious. However, for increased intelligibility, each aspect will only be described in detail when first mentioned and any repeated description of the same aspect will be omitted.

The above and other aspects and their implementations are described in greater detail in the drawings, the descriptions, and the claims.

### BRIEF DESCRIPTION OF THE DRAWINGS

FIG. 1 illustrates a conventional electrical power grid.

FIG. 2 illustrates a flowchart of a method according to an embodiment of the present disclosure.

FIG. 3 a) illustrates an electrical power distribution system according to an embodiment of the present disclosure under a normal operating condition.

FIG. 3 b) illustrates an electrical power distribution system according to an embodiment of the present disclosure under a fault condition.

FIG. 3 c) illustrates an electrical power distribution system according to an embodiment of the present disclosure under a fault condition.

FIG. 3 d) illustrates an electrical power distribution system according to an embodiment of the present disclosure under a fault condition.

FIG. 3 e) illustrates an electrical power distribution system according to an embodiment of the present disclosure under a post-fault normal operating condition.

FIG. 4 illustrates a flowchart of a method according to an embodiment of the present disclosure.

FIG. 5 illustrates a flowchart for a fault location determination method according to an embodiment of the present disclosure.

FIG. 6 illustrates a flowchart for a post-fault re-start process according to an embodiment of the present disclosure.

FIG. 7 illustrates an electrical power distribution system according to an embodiment of the present disclosure.

FIG. 8 a) illustrates a controller for an electrical power distribution system according to an embodiment of the present disclosure.

FIG. 8 b) illustrates an electrical power distribution system according to an embodiment of the present disclosure.

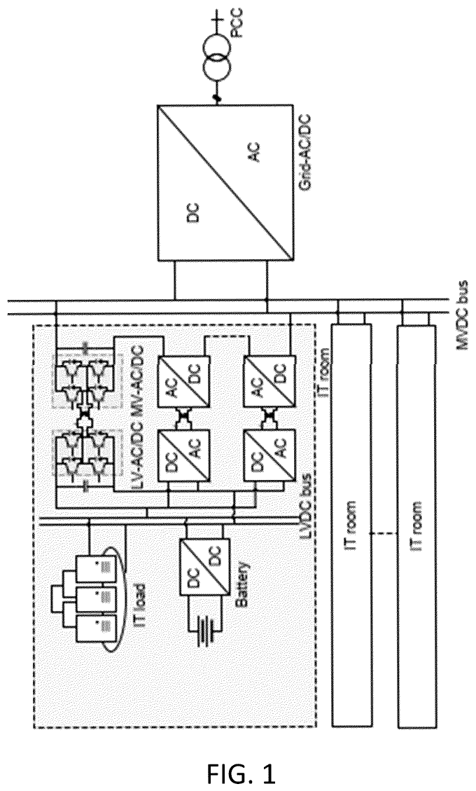

### DETAILED DESCRIPTION OF THE DISCLOSURE

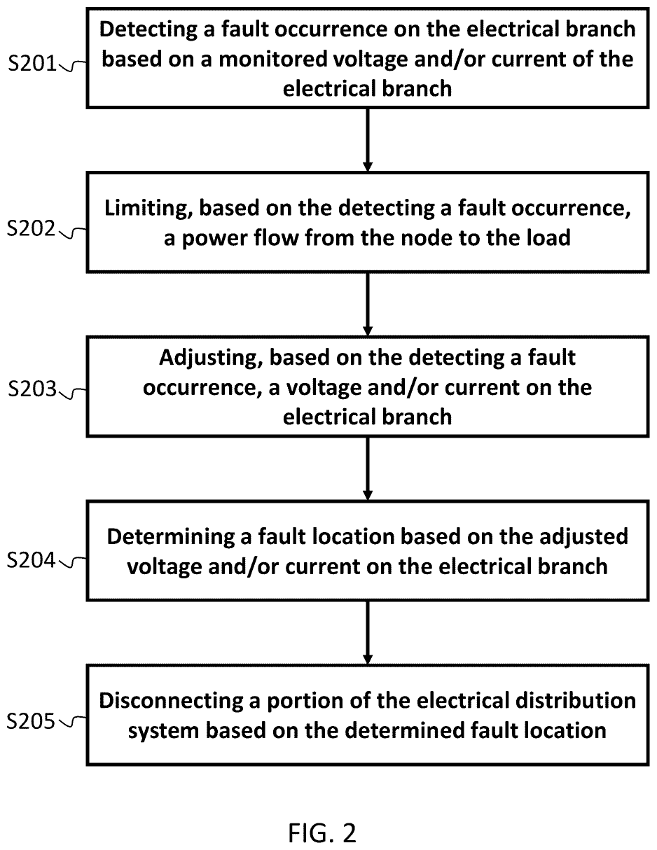

FIG. 2 illustrates a flowchart of a method according to an embodiment of the present disclosure. In particular, the method is for protecting an electrical distribution system comprising an electrical grid being electrically coupled to an electrical branch comprising a plurality of switches for connecting or disconnecting the electrical branch at respective positions on the electrical branch, wherein a load is electrically coupled to a node on the electrical branch. The electrical distribution system may be equivalently referred to as an electrical power distribution system.

At S201, a fault occurrence on the electrical branch is detected based on a monitored voltage and/or current of the electrical branch. The monitored voltage and/or current may be measured at any position on the electrical branch, in particular at any one of the respective positions of the plurality of switches. The detecting may be based on the voltage and/or current measured at any position on the electrical branch, in particular the voltage and/or current measured at the respective positions of the plurality of switches. The detecting may be further based on any other electrical or physical parameter of the electrical distribution system and/or any components comprised therein.

At S202, a power flow from the node to the load is limited based on the detecting a fault occurrence. The term ‘limit’ may be semantically equivalent to, thus can be interchangeably used with, other terms such as ‘change’, ‘reduce’, ‘block’, ‘cut-off’, or the like. In an embodiment, the limiting is or comprises controlling a galvanic isolator which electrically couples the load to the node. The galvanic isolator may be a solid-state transformer (SST). In an embodiment, the limiting is performed after performing S201 and/or before performing S203. The limiting of S202 may be performed even when having determined that a fault has not occurred, for instance when a fault occurrence detection yields a false-negative response.

At S203, a voltage and/or current on the electrical branch is adjusted based on the detecting a fault occurrence. It is understood by the skilled person that the term ‘adjust’ may be semantically equivalent to, thus can be interchangeably used with, other terms such as ‘set’, ‘control’, or the like. In an embodiment, the adjusting is or comprises injecting a predetermined current into the electrical branch. In an embodiment, the adjusting is or comprises controlling a power converter, wherein the power converter electrically couples the electrical grid to the electrical branch. In an embodiment, the adjusting is performed after performing S202 and/or before performing S204. The adjusting of S203 may be performed even when having determined that a fault has not occurred, for instance when a fault occurrence detection yields a false-negative response.

At S204, a fault location is determined based on the adjusted voltage and/or current on the electrical branch. The adjusted voltage and/or current may be measured at any position on the electrical branch, in particular at any one of the respective positions of the plurality of switches. A fault location may be a fault range, wherein a fault is located inside the fault range. In an embodiment, a fault range is determined by the adjusted voltage and/or current measured at at least two different positions, in particular the at least two different positions at which two different switches of the plurality of switches are respectively located, on the electrical branch, wherein the fault range is between the at least two different switches of the plurality of switches. In an embodiment, the determining a fault location is based on the adjusting the current on the electrical branch.

At S205, a portion of the electrical distribution system is disconnected based on the determined fault location. In an embodiment, the disconnecting is or comprises disconnecting at least two switches of the plurality of switches, when having determined that a fault location resides on the electrical branch between the at least two switches.

In an embodiment, the method further comprises limiting a power flow from the electrical grid to the electrical branch. The said limiting may be performed after performing S203 and/or before performing S205. The said limiting may be or comprise controlling a power converter, wherein the power converter electrically couples the electrical grid to the electrical branch.

In an embodiment, the method further comprises re-operating the power distribution system by: de-limiting, after the disconnecting (S205), the limited power flow from the node to the load; and controlling, after the disconnecting (S205), a power flow from the electrical grid to the load. The re-operating may be performed after S205. The term ‘de-limit’ may be semantically equivalent to, thus can be interchangeably used with, other terms such as ‘change’, ‘increase’, ‘de-block’, or the like. In an embodiment, the de-limiting is or comprises controlling a galvanic isolator electrically coupling the load to the node. The galvanic isolator may be a solid-state transformer (SST).

In an embodiment, the at least two switches of the plurality of switches are adjacent to each other, in particular having the node located between the at least two switches of the plurality of switches.

In an embodiment, two ends of the electrical branch are electrically coupled to a power converter forming a loop. The power converter electrically couples the electrical grid to the electrical branch. The loop may be a ring main unit. The loop may be electrically disconnected by at least one of the plurality of switches disconnecting the electrical branch. In the same embodiment, the re-operating further comprises re-connecting the at least one of the plurality of switches disconnecting the electrical branch. In the same embodiment, the adjusting further comprises enabling a power flow from the electrical grid to the electrical branch.

In an embodiment, one end of two ends of the electrical branch is electrically coupled to a first power converter, wherein the first power converter is further electrically coupled to the electrical grid; and the other end of the two ends of the electrical branch is electrically coupled to a second power converter, wherein the second power converter is further electrically coupled to the electrical grid. In the same embodiment, at least one of the plurality of switches disconnects the electrical branch. In the same embodiment, the re-operating further comprises re-connecting the at least one of the plurality of switches disconnecting the electrical branch. In the same embodiment, the adjusting further comprises enabling a power flow from the electrical grid to the electrical branch. In the embodiment, the adjusting is or comprises injecting a predetermined current into the electrical branch, in particular by controlling the first power converter and the second power converter. In the same embodiment, the method further comprises limiting a power flow from the electrical grid to the electrical branch. The said limiting may be performed after performing S203 and/or before performing S205. The said limiting may be or comprise controlling the first power converter and/or the second power converter. The said limiting may be or comprise, when at least one of the plurality of switches disconnects the electrical branch, limiting the first power converter when having determined that a fault location is between the first power converter and the position at which the at least one of the plurality of switches disconnecting the electrical branch is located; or limiting the second power converter when having determined that a fault location is between the second power converter and the position at which the at least one of the plurality of switches disconnecting the electrical branch is located.

Herein, the term ‘disconnector’ may be interchangeably used with the term ‘switch’.

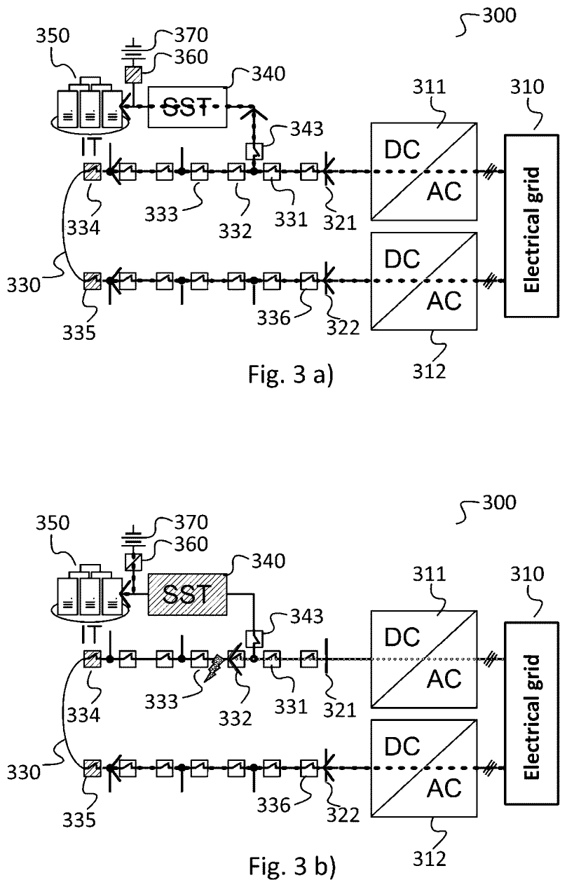

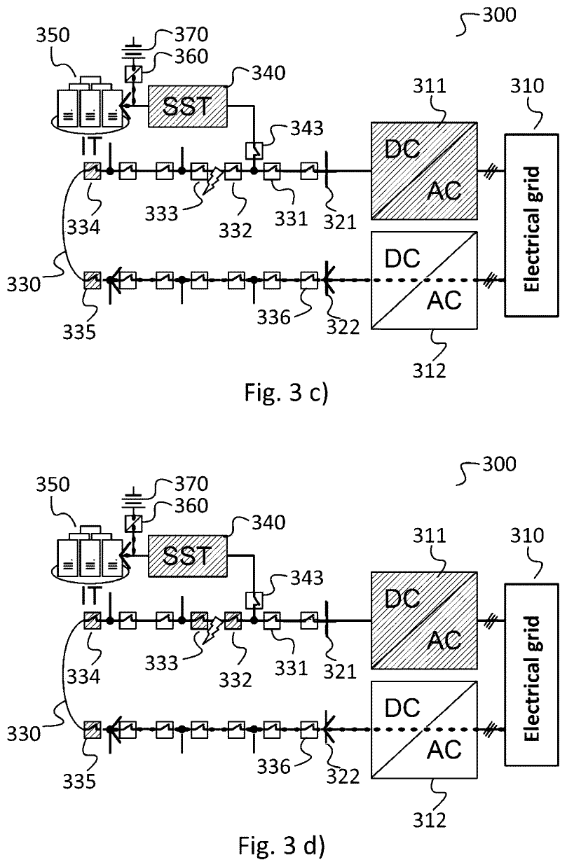

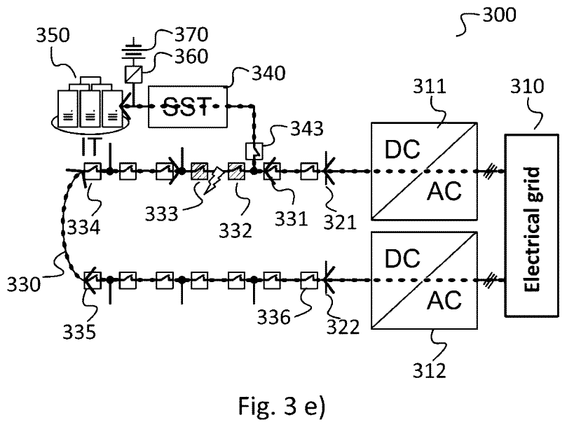

FIG. 3 a) through FIG. 3 e) illustrate electrical distribution systems according to embodiments of the present disclosure operating based on an exemplary method disclosed herein. In particular, the electrical distribution system 300 comprises an electrical grid 310 being electrically coupled to an electrical branch 330 comprising a plurality of switches 331, 332, 333, 334, 335, and 336 for connecting or disconnecting the electrical branch 330 at respective positions on the electrical branch 330, wherein a load 350 is electrically coupled to a node on the electrical branch 330. For legibility, only a selection of the plurality of switches 331, 332, 333, 334, 335, and 336 are referred to with the reference numerals in FIG. 3 a) through FIG. 3 e), and the numbering starts from the upper portion of the electrical branch 330 having one of the two ends being electrically coupled to the first power converter 311 and increases along the electrical branch 330 until the other end of the two ends of the electrical branch. The electrical grid 310 is electrically coupled to one end of two ends of the electrical branch 330 via a first power converter 311, and is electrically coupled to the other end of the two ends of the electrical branch 330 via a second power converter 312. The electrical grid 310 may be electrically coupled to the first power converter 311 and second power converter 312 via a point of common coupling (PCC). The electrical grid 310 may be a power source, in particular an AC power source, more particularly an AC network. The electrical grid 310 may comprise the PCC. The first and second power converters 311 and 312 are AC/DC power converters. The load 350 is electrically coupled to the node via an SST 340, wherein the node is positioned on the electrical branch between a second switch 331 and third switch 332 of the plurality of switches 331, 332, 333, 334, 335, and 336. The SST 330 is electrically coupled to the node on the electrical branch 330 via an auxiliary switch 343. A set of two consecutive switches comprising a node to which a load is electrically coupled to may be referred to as consecutive two switches. For instance, the second switch 331 and third switch 332 are two consecutive switches. The seventh switch 334 and the eighth switch 335 of the electrical branch 330 are disconnecting the electrical branch 330. It is understood by the skilled person that any other switch(es) of the plurality of switches 331, 332, 333, 334, 335, and 336 may be selected for disconnecting the electrical branch. Such disconnection configuration enables the power to flow into the electrical branch 330 from the first and second power converters 311 and 312. A first bus 321 is electrically coupling the first power converter 311 to the one end of the two ends of the electrical branch 330, and a second bus 322 is electrically coupling the second power converter 312 to the other end of the two ends of the electrical branch 330. The first bus 321 or second bus 322 may be any one of an electrical interconnection, an electrical bus, an electrical busbar, a PCC. Also, an external power source 370 (e.g., a battery), in particular different from the electrical grid 310, is electrically coupled to the IT load 350 via a DC-to-DC (DC/DC) power converter 360. The DC/DC power converter 360 may be replaced with a switch. It is understood by the skilled person that further loads can be electrically coupled to the electrical branch 330. It is further understood by the skilled person that an MVDC system is illustrated in FIG. 3 a) through FIG. 3 e) for an illustrative purpose and that the method disclosed herein is also applicable to any AC and/or DC system.

FIG. 3 a) illustrates an electrical power distribution system according to an embodiment of the present disclosure under a normal operating condition. The term ‘normal operating condition’ refers to an abnormality-free operational condition. For instance, an abnormality may be a fault, e.g., short-circuit fault, on the electrical branch. For instance, an abnormality may be a failure in any of the electrical components comprised in the electrical distribution system. Under normal operating condition, the power is delivered from the electrical grid 310 to the first and second buses 321 and 322 via the respective first and second power converters 311 and 312, and is further delivered from the first and second buses 321 and 322 to the loads that are electrically coupled to the electrical branch 330. Under normal operating condition, the power flow from the external power source 370 to the IT load 350 is limited by the DC/DC power converter 360. Under normal operating condition, a fault occurrence on the electrical branch 330 is detected based on a monitored voltage and/or current of the electrical branch. The above-described method may be an embodiment of S201. Such fault occurrence detection may be performed iteratively. While performing the above-described method, the seventh and eighth switches 334 and 335 are disconnecting the electrical branch 330. Once a fault on the electrical branch is detected, the electrical power distribution system 300 performs the following method according to an embodiment of the present disclosure as illustrated in FIG. 3 b).

FIG. 3 b) illustrates an electrical power distribution system according to an embodiment of the present disclosure under a fault condition. When a fault (illustrated with a lightning bolt in FIG. 3 b) through FIG. 3 e)) occurs on the electrical branch 330 between a third switch 332 and fourth switch 333 of the plurality of switches 331, 332, 333, 334, 335, and 336, and when the fault is detected, for instance according to S201, the power flow from the node to the IT load 350 is limited by controlling the SST 340. It is noted that the exact fault location on the electrical branch may be undetermined at this stage, but a mere detection of a fault occurrence may suffice. Simultaneously or prior to limiting the power flow from the node (i.e., on the electrical branch 330 between the second switch 331 and third switch 332, to which the IT load 350 is electrically coupled) to the IT load 350, the DC/DC power converter 360 is controlled to enable the power flow from the external power source 370 to the IT load 350, such that the power delivery to the IT load 350 is uninterrupted during the fault clearance process disclosed herein. The above-described method may be an embodiment of S202. Once the power flow from the node to the IT load 350 is limited, the current on the electrical branch 330 may be adjusted by controlling the first power converter 311 and the second power converter 312 to inject a pre-determined current into the electrical branch 330. The above-described method may be an embodiment of S203. Then, a fault location is determined based on the adjusted current on the electrical branch 330. The above-described method may be an embodiment of S204. While performing the above-described method, the seventh and eighth switches 334 and 335 are still disconnecting the electrical branch 330. Once the fault location is determined, the electrical power distribution system 300 performs the following method according to an embodiment of the present disclosure as illustrated in FIG. 3 c).

FIG. 3 c) illustrates an electrical power distribution system according to an embodiment of the present disclosure under a fault. Once the fault location is determined to reside between the third switch 332 and fourth switch 333 of the plurality of switches 331, 332, 333, 334, 335, and 336, the power flow from the electrical grid 310 to the electrical branch 330 is limited by controlling the first power converter 311. In an embodiment, the second power converter 312 is also controlled in a likewise manner. In particular, in case a fault is determined to reside between the eighth switch 335 and the fourteenth switch 336, the power flow from the electrical grid 310 to the electrical branch 330 is limited by controlling the second power converter 312. In an embodiment, both the first power converter 311 and second power converter 312 are controlled to limit said power flow. While performing the above-described method, the seventh and eighth switches 334 and 335 are still disconnecting the electrical branch 330. Then, a fault point isolation method according to an embodiment of the present disclosure is performed as illustrated in FIG. 3 d).

FIG. 3 d) illustrates an electrical power distribution system according to an embodiment of the present disclosure under a fault. When having determined that a fault is located between the third switch 332 and fourth switch 333 and the power flow from the electrical grid 310 to the electrical branch 330 is controlled, a portion of the electrical branch 330 is disconnected by opening the third switch 332 and fourth switch 333, i.e., disconnecting the electrical branches at the respective positions of the third switch 332 and fourth switch 333. It is understood by the skilled person that in this embodiment, for an illustrative purpose, the two switches (i.e., the third switch 332 and fourth switch 333) that are most adjacent to the fault location are disconnected to isolate the fault, but it is possible to disconnect any portion of the electrical branch by controlling any combination of at least two switches of the plurality of switches 331, 332, 333, 334, 335, and 336 for the same purpose, as long as the fault resides within the selected combination of at least two switches. For instance, the third switch 332 and the seventh switch 334 may be controlled to disconnect a portion of the electrical branch therebetween. The above-described method may be an embodiment of S205.

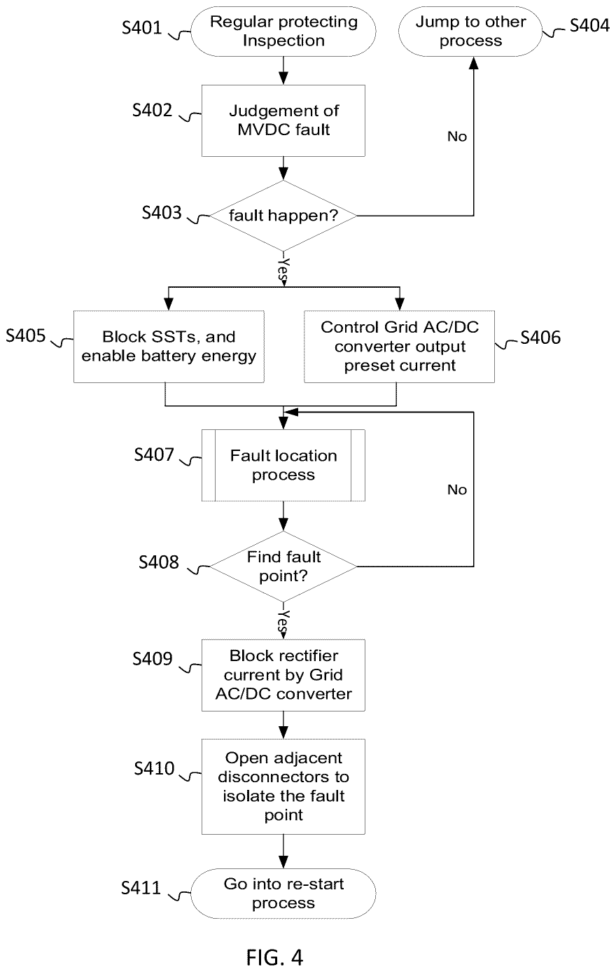

FIG. 3 e) illustrates an electrical power distribution system according to an embodiment of the present disclosure under a post-fault normal operation. After disconnecting a portion of the electrical branch 330 between the third switch 332 and fourth switch 333, the power flow from the external power source 370 is limited by the DC/DC power converter 360, and the IT load 350 receives power from the electrical grid 310. That is, the re-operating under a post-fault normal operating condition comprises enabling the power flow from the electrical grid 310 to the electrical branch 330 by controlling the first power converter 311 and the second power converter 312; and enabling the power flow from the node to the IT load 350 by controlling the SST 340. In this embodiment, the seventh switch 334 and the eighth switch 335 are closed, i.e., connecting the electrical branch 330 at the respective positions thereof, such that the power is delivered to the portion of the electrical branch 330 between the fourth switch 333 and the seventh switch 334 via the second power converter 312, after the power delivery to the said portion is interrupted by the isolated portion of the electrical branch 330 around the fault location. The method illustrated in FIG. 4 may be implemented in combination with the electrical distribution system illustrated in FIG. 3 a) through FIG. 3 e).

FIG. 4 illustrates a flowchart of a method according to an embodiment of the present disclosure. At S401, a regular protecting inspection is performed. At S402, an MVDC fault is determined. S402 may be equivalent to S201. At S403, a further action is decided based on the fault occurrence determined at S402. When a fault is not detected, the method jumps to other process (S404). In an embodiment, the other process of S404 includes the fault detection of S402. When a fault is detected, the SST is blocked, the battery energy is enabled (S405), and grid AC/DC converter output is controlled to output a pre-set current (S406). Then, at S407, a fault location process is executed, wherein a fault point is iteratively checked until determined (S408). In an embodiment, after a pre-defined number of iterations or a pre-defined period of time, the loop formed by S407, S408, and the negative result of S408 breaks and the method jumps to another block, for instance S409. In the same embodiment, after the pre-defined number of iterations or the pre-defined period of time, the fault point may be determined as a pre-defined location on the electrical branch. Blocks S405 through S408 may correspond to the method illustrated with the system shown in FIG. 3 b). Once a fault location is determined, the rectifier current set by S406 is blocked by controlling the grid AC/DC converter (S409). S409 may correspond to the method illustrated with the system shown in FIG. 3 c). Then, the fault point is isolated by opening the adjacent switches (S410). S410 may correspond to the method illustrated with the system shown in FIG. 3 d). At S411, the system enters a re-start process. S411 may correspond to the method illustrated with the system shown in FIG. 3 e). The term ‘re-start’ or ‘re-operate’ refers to an action of controlling the relevant components comprised in a system to return to a normal operation, in particular after a protective measurement such as disconnecting a portion of the electrical branch is applied thereto.

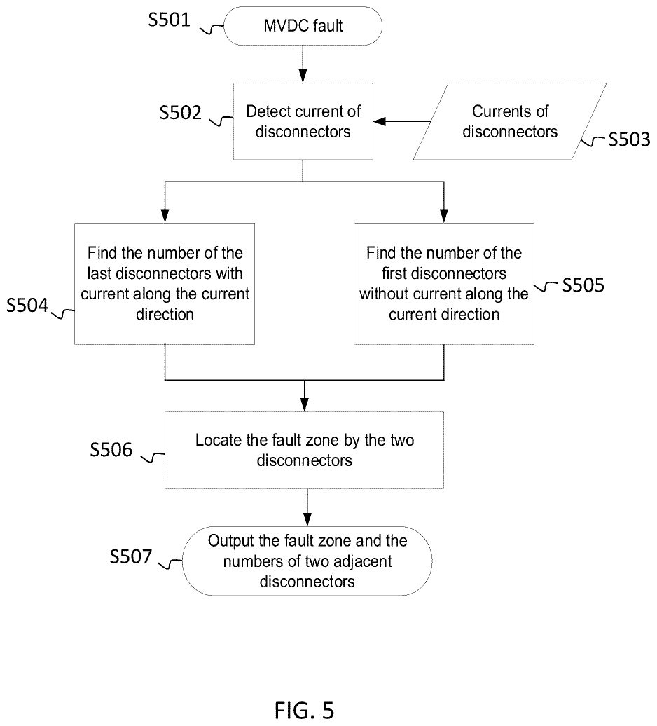

FIG. 5 illustrates a flowchart for a fault location determination method according to an embodiment of the present disclosure. The method illustrated in FIG. 5 may be an embodiment of the fault location determination of S407. When an MVDC fault is detected, the current on the electrical branch may be adjusted, in particular a predetermined current may be injected into the electrical branch by controlling the first power converter and the second power converter, as illustrated in FIG. 3 b). At S502, the adjusted currents are measured at the respective positions of the plurality of switches on the electrical branch (S503). Then, the number of the last disconnector with current along the current direction is found at S504. That is, the position of a last switch through which the adjusted current passes, in particular within a pre-determined range, is determined. For instance, in reference to FIG. 3 b), the current flows from the first bus 321 to the seventh switch 334, and the third switch 332 is determined to be the last switch through which the injected current passes. The number of the first disconnector without current along the current direction is found at S505. That is, the position of a first switch through which the adjusted current does not pass through is determined. At S506, the fault zone is located by the two disconnectors identified at S504 and S505. That is, said positions determined at S504 and S505 indicate that a fault is located therebetween. At S507, the fault zone and the two disconnectors identified at S504 and S505 are outputted for a further processing or signal generation.

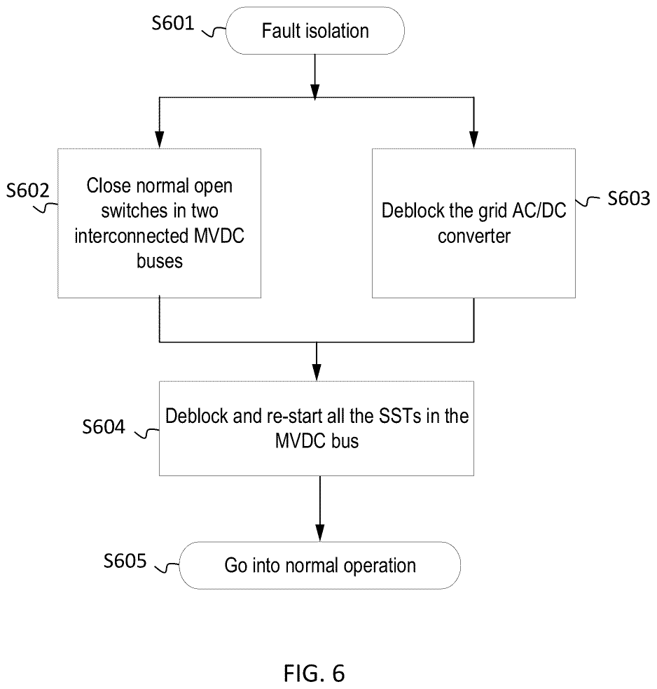

FIG. 6 illustrates a flowchart for a post-fault re-start process according to an embodiment of the present disclosure. The method illustrated in FIG. 6 may be an embodiment of the re-start process of S411. At S601, a fault isolation is performed. S601 may correspond to S410. At S602, switches that are opened under normal operating condition are closed, and at S603, the grid AC/DC converter is deblocked. For instance, in reference to FIG. 3 e), the seventh switch 334 and eighth switch 335 are closed (S603) and the first power converter 311 and second power converter 312 are controlled to enable the power flow from the electrical grid 310 to the electrical branch 330. At S604, all the SSTs in the MVDC bus are deblocked and re-started. For instance, in reference to FIG. 3 e), the SST 340 is controlled to enable the electrical flow from the electrical branch 330 to the IT load 350. At S605, the electrical power distribution system operates under a normal operating condition again.

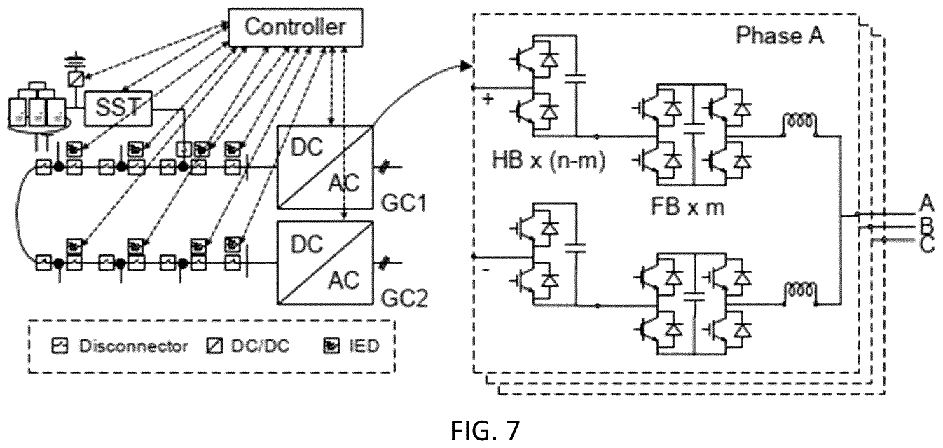

FIG. 7 illustrates an electrical power distribution system according to an embodiment of the present disclosure. In particular, the electrical power distribution system comprises the systems illustrated in FIG. 3 a) through FIG. 3 e) and further comprises a controller and a plurality of intelligent electronic devices (IEDs). The controller is configured to perform the method according to any one of the embodiments disclosed herein. The controller may be further configured to communicate, particularly bidirectionally, with any one of the components comprised in the system. In an embodiment, the controller receives or obtains measurements and/or signals and generate control and/or communication signals based on the received or obtained measurements and/or signals. Each of the plurality of IEDs may be or comprise a voltage and/or current sensor. Each of the plurality of IEDs may be located at the respective positions of the plurality of switches comprised in the electrical branch for connecting and disconnecting the electrical branch at said respective positions. It is understood by the skilled person that the number of the plurality of IEDs may be different from the number of the plurality of switches. The controller may be configured to control the plurality of switches. The plurality of IEDs may be configured to control the plurality of switches. The grid AC/DC converter may be or comprise a modular multilevel converter (MMC) with full-bridge cells as illustrated in FIG. 7. The MMC may comprise m full-bridge cells in a branch. In an embodiment, m is given as

$$n \leq m \leq ceil ( \frac{\sqrt{6} {U}_{a c , max}}{{U}_{c , min}} ) \qquad ( 1 )$$

wherein, n is a number of all cells in an electrical branch, ceil( ) is a function to round the element to the nearest integer towards infinity, U_{ac,max} is the maximum voltage of the AC grid, and U_{c,min} is the minimum voltage of the cells in operation, assuming that voltages of all the cells are the same.

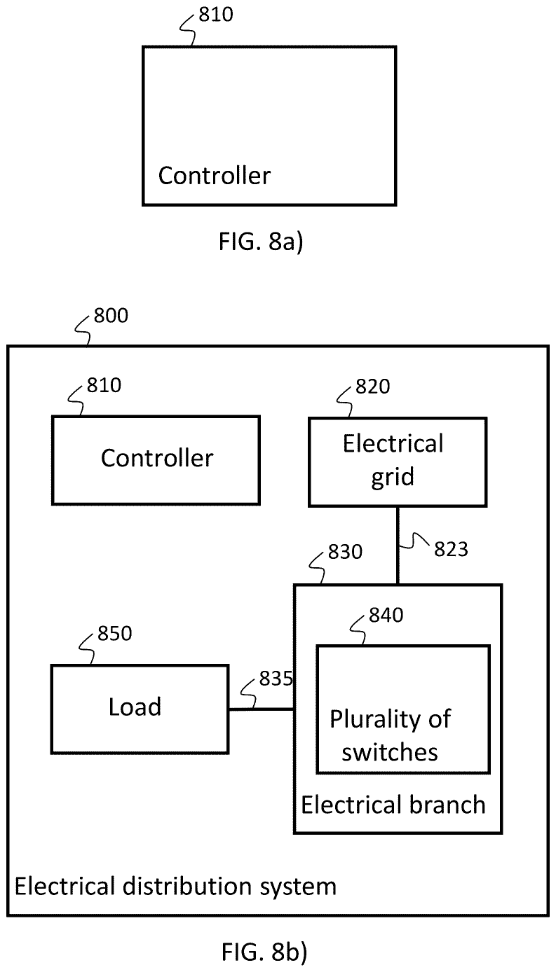

FIG. 8 a) illustrates a controller for an electrical power distribution system according to an embodiment of the present disclosure. The controller 810 may be the controller illustrated in FIG. 7. In an embodiment, the controller 810 is further configured to perform the method according to any one of the embodiments disclosed herein. The controller 810 is a controller for protecting an electrical distribution system 800 comprising an electrical grid 820 being electrically coupled 823 to an electrical branch 830, the electrical branch 830 comprising a plurality of switches 840 for connecting or disconnecting the electrical branch 830 at respective positions on the electrical branch 830, wherein a load 850 is electrically coupled 835 to a node on the electrical branch 830, the controller being configured to: detect a fault occurrence on the electrical branch 830 based on a monitored voltage and/or current of the electrical branch; limit, based on the detecting a fault occurrence, a power flow from the node to the load 850; adjust, based on the detecting a fault occurrence, a voltage and/or current on the electrical branch 830; determine a fault location based on the adjusted voltage and/or current on the electrical branch 830; and disconnect a portion of the electrical distribution system 800 based on the determined fault location.

FIG. 8 b) illustrates an electrical power distribution system according to an embodiment of the present disclosure. The electrical distribution system 800 is an electrical distribution system comprising an electrical grid 820 being electrically coupled 823 to an electrical branch 830, the electrical branch 830 comprising a plurality of switches 840 for connecting or disconnecting the electrical branch 830 at respective positions on the electrical branch 830, wherein a load 850 is electrically coupled 835 to a node on the electrical branch 830, the electrical distribution system 800 further comprising the controller according to any one of the embodiments disclosed herein.

While various embodiments of the present disclosure have been described above, it should be understood that they have been presented by way of example only, and not by way of limitation. Likewise, the various diagrams may depict an example architectural or configuration, which are provided to enable persons of ordinary skill in the art to understand exemplary features and functions of the present disclosure. Such persons would understand, however, that the present disclosure is not restricted to the illustrated example architectures or configurations, but can be implemented using a variety of alternative architectures and configurations. Additionally, as would be understood by persons of ordinary skill in the art, one or more features of one embodiment can be combined with one or more features of another embodiment described herein. Thus, the breadth and scope of the present disclosure should not be limited by any of the above-described exemplary embodiments.

It is also understood that any reference to an element herein using a designation such as “first,” “second,” and so forth does not generally limit the quantity or order of those elements. Rather, these designations can be used herein as a convenient means of distinguishing between two or more elements or instances of an element. Thus, a reference to first and second elements does not mean that only two elements can be employed, or that the first element must precede the second element in some manner.

Additionally, a person having ordinary skill in the art would understand that information and signals can be represented using any of a variety of different technologies and techniques. For example, data, instructions, commands, information, signals, bits and symbols, for example, which may be referenced in the above description can be represented by voltages, currents, electromagnetic waves, magnetic fields or particles, optical fields or particles, or any combination thereof.

A skilled person would further appreciate that any of the various illustrative logical blocks, units, processors, means, circuits, methods and functions described in connection with the aspects disclosed herein can be implemented by electronic hardware (e.g., a digital implementation, an analog implementation, or a combination of the two), firmware, various forms of program or design code incorporating instructions (which can be referred to herein, for convenience, as “software” or a “software unit”), or any combination of these techniques.

To clearly illustrate this interchangeability of hardware, firmware and software, various illustrative components, blocks, units, circuits, and steps have been described above generally in terms of their functionality. Whether such functionality is implemented as hardware, firmware or software, or a combination of these techniques, depends upon the particular application and design constraints imposed on the overall system. Skilled artisans can implement the described functionality in various ways for each particular application, but such implementation decisions do not cause a departure from the scope of the present disclosure. In accordance with various embodiments, a processor, device, component, circuit, structure, machine, unit, etc. can be configured to perform one or more of the functions described herein. The term “configured to” or “configured for” as used herein with respect to a specified operation or function refers to a processor, device, component, circuit, structure, machine, unit, etc. that is physically constructed, programmed and/or arranged to perform the specified operation or function.

Furthermore, a skilled person would understand that various illustrative methods, logical blocks, units, devices, components and circuits described herein can be implemented within or performed by an integrated circuit (IC) that can include a general purpose processor, a digital signal processor (DSP), an application specific integrated circuit (ASIC), a field programmable gate array (FPGA) or other programmable logic device, or any combination thereof. The logical blocks, units, and circuits can further include antennas and/or transceivers to communicate with various components within the network or within the device. A general purpose processor can be a microprocessor, but in the alternative, the processor can be any conventional processor, controller, or state machine. A processor can also be implemented as a combination of computing devices, e.g., a combination of a DSP and a microprocessor, a plurality of microprocessors, one or more microprocessors in conjunction with a DSP core, or any other suitable configuration to perform the functions described herein. If implemented in software, the functions can be stored as one or more instructions or code on a computer-readable medium. Thus, the steps of a method or algorithm disclosed herein can be implemented as software stored on a computer-readable medium.

Computer-readable media includes both computer storage media and communication media including any medium that can be enabled to transfer a computer program or code from one place to another. A storage media can be any available media that can be accessed by a computer. By way of example, and not limitation, such computer-readable media can include RAM, ROM, EEPROM, CD-ROM or other optical disk storage, magnetic disk storage or other magnetic storage devices, or any other medium that can be used to store desired program code in the form of instructions or data structures and that can be accessed by a computer.

Additionally, memory or other storage, as well as communication components, may be employed in embodiments of the present disclosure. It will be appreciated that, for clarity purposes, the above description has described embodiments of the present disclosure with reference to different functional units and processors. However, it will be apparent that any suitable distribution of functionality between different functional units, processing logic elements or domains may be used without detracting from the present disclosure. For example, functionality illustrated to be performed by separate processing logic elements, or controllers, may be performed by the same processing logic element, or controller. Hence, references to specific functional units are only references to a suitable means for providing the described functionality, rather than indicative of a strict logical or physical structure or organization.

Various modifications to the implementations described in this disclosure will be readily apparent to those skilled in the art, and the general principles defined herein can be applied to other implementations without departing from the scope of this disclosure. Thus, the disclosure is not intended to be limited to the implementations shown herein, but is to be accorded the widest scope consistent with the novel features and principles disclosed herein, as recited in the claims below.

1-15. (canceled)

16. A method for protecting an electrical distribution system comprising an electrical grid being electrically coupled to an electrical branch, the electrical branch comprising a plurality of switches for connecting or disconnecting the electrical branch at respective positions on the electrical branch, wherein a load is electrically coupled to a node on the electrical branch, the method comprising:
detecting a fault occurrence on the electrical branch based on a monitored voltage and/or current of the electrical branch;
limiting, based on the detecting a fault occurrence, a power flow from the node to the load;
adjusting, based on the detecting a fault occurrence, a voltage and/or current on the electrical branch;
determining a fault location based on the adjusted voltage and/or current on the electrical branch; and
disconnecting a portion of the electrical distribution system based on the determined fault location,
wherein the disconnecting is or comprises disconnecting at least two switches of the plurality of switches, when having determined that a fault location resides on the branch between the at least two switches.

17. The method of claim 16, wherein the limiting is or comprises controlling a galvanic isolator electrically coupling the load to the node.

18. The method of claim 16, wherein
the adjusting is or comprises injecting a predetermined current into the electrical branch, in particular by controlling a power converter electrically coupling the electrical grid to the electrical branch, and
a fault location is determined based on the adjusted current.

19. The method of claim 16, further comprising limiting, prior to the disconnecting, a power flow from the electrical grid to the electrical branch, in particular by controlling a power converter electrically coupling the electrical grid to the electrical branch.

20. The method of claim 16, wherein the at least two switches of the plurality of switches are adjacent to each other, in particular having the node located between the at least two switches.

21. The method of claim 16, the method further comprising re-operating the electrical distribution system by:
de-limiting, after the disconnecting, the limited power flow from the node to the load; and
controlling, after the disconnecting, a power flow from the electrical grid to the load.

22. The method of claim 16, wherein two ends of the electrical branch are electrically coupled to a power converter, electrically coupling the electrical grid to the electrical branch, forming a loop.

23. The method of claim 16, wherein
one end of two ends of the electrical branch is electrically coupled to a first power converter being further electrically coupled to the electrical grid and the other end of the two ends of the electrical branch is electrically coupled to a second power converter being further electrically coupled to the electrical grid, and
at least one of the plurality of switches disconnects the electrical branch.

24. The method of claim 23, wherein the adjusting further comprises enabling a power flow from the electrical grid to the electrical branch, in particular by controlling the second power converter.

25. The method of claim 23, wherein
the adjusting is or comprises injecting a predetermined current into the electrical branch, in particular by controlling the first power converter and the second power converter, and
the determining a fault location is based on the adjusting the current on the electrical branch.

26. The method of claim 23, the method further comprising re-operating the electrical distribution system by:
de-limiting, after the disconnecting, the limited power flow from the node to the load; and
enabling, after the disconnecting, a power flow from the electrical grid to the load, in particular by controlling the first power converter and the second power converter.

27. A controller for protecting an electrical distribution system comprising an electrical grid being electrically coupled to an electrical branch, the electrical branch comprising a plurality of switches for connecting or disconnecting the electrical branch at respective positions on the electrical branch, wherein a load is electrically coupled to a node on the electrical branch, the controller being configured to:
detect a fault occurrence on the electrical branch based on a monitored voltage and/or current of the electrical branch;
limit, based on the detecting a fault occurrence, a power flow from the node to the load;
adjust, based on the detecting a fault occurrence, a voltage and/or current on the electrical branch;
determine a fault location based on the adjusted voltage and/or current on the electrical branch; and
disconnect a portion of the electrical distribution system based on the determined fault location,
wherein the controller is configured to disconnect at least two switches of the plurality of switches, when having determined that a fault location resides on the branch between the at least two switches.

28. The controller of claim 27, wherein the limiting is or comprises controlling a galvanic isolator electrically coupling the load to the node.

29. An electrical distribution system comprising an electrical grid being electrically coupled to an electrical branch, the electrical branch comprising a plurality of switches for connecting or disconnecting the electrical branch at respective positions on the electrical branch, wherein a load is electrically coupled to a node on the electrical branch, the electrical distribution system further comprising the controller of claim 27.
